(19) United States
(12) Patent Application Publication
(10) Pub. No.: US 2016/0372442 A1
(43) Pub. Date: Dec. 22, 2016

(54) DISPLAY DEVICE

(71) Applicant: SHENZHEN CHINA STAR OPTOELECTRONICS TECHNOLOGY CO., LTD., Shenzhen, Guangdong (CN)

(72) Inventors: Bing HAN, Shenzhen, Guangdong (CN); Shih Hsun LO, Shenzhen, Guangdong (CN); Jinjie WANG, Shenzhen, Guangdong (CN)

(21) Appl. No.: 14/416,788

(22) PCT Filed: Dec. 9, 2014
(86) PCT No.: PCT/CN2014/093387

§ 371 Date: Jan. 23, 2015

(30) Foreign Application Priority Data
Oct. 20, 2014 (CN) 201410557552.2

(51) Int. Cl. H01L 23/00; G02F 1/133

(52) U.S. Cl. CPC H01L 24/49; G02F 1/13306; H01L 24/48; H01L 2224/16227; H01L 2224/16054; H01L 2224/1703; H01L 2224/17106; H01L 2924/30101

(57) ABSTRACT

In the technical field of display, a display device for solving the technical problem of fanout mura of the pixels controlled by the wires located at both sides of a fanout is provided. The display device according to the present disclosure comprises a substrate, and a chip on film connected to the fanout on the substrate through a bounding lead. The bounding lead comprises a plurality of parallel wires. In the bounding lead, the areas of the wires gradually decrease from the wires located at both ends of the bounding lead to those located at the center thereof. The present disclosure can be applied to display devices, such as liquid crystal television and liquid crystal display, etc.

The present application claims benefit of Chinese patent application CN 201410557552.2, entitled “DISPLAY DEVICE” and filed on Oct. 20, 2014, which is incorporated herein by reference.

### TECHNICAL FIELD

The present disclosure relates to the technical field of display, and in particular, to a display device.

### TECHNICAL BACKGROUND

As display technology develops, a liquid crystal display device has become a commonly used panel display device.

In a liquid crystal display device, the pixels are controlled by gate lines and data lines that are arranged in a staggered manner with respect to each other on a substrate, so as to display images. A gate driving signal and a data signal are sent out from a control chip in the liquid crystal display device, and transmitted to the gate lines and data lines on the substrate respectively through a chip on film (hereinafter referred to as COF).

Specifically, a COF is connected to a fanout on the substrate through a bounding lead, and then connected to the gate lines and data lines in an active area. In the prior art, a bounding lead comprises a plurality of rectangular wires, each corresponding to one of the wires in the fanout. Because the fanout appears as a fan shape as a whole, the wires located at both sides of the fanout would be much longer than those located at the center, rendering much larger resistance of the wires at both sides than those at the center. As a result, severe distortion would occur to the waveform of the gate driving signal or that of the data signal transmitted through the wires located at both sides, producing color cast. In this case, the pixels controlled by the wires located at both sides of the fanout would appear as fanout mura, thereby having a negative influence on the display effect of the liquid crystal display device.

### SUMMARY OF THE INVENTION

The objective of the present disclosure is to provide a display device, so as to solve the technical problem of fanout mura of the pixels controlled by the wires at both sides of the fanout.

The present disclosure provides a display device, comprising a substrate, and a chip on film connected to a fanout on the substrate through a bounding lead, wherein

the bounding lead comprises a plurality of parallel wires, and

in the bounding lead, the areas of the wires gradually decrease from the wires located at both ends of the bounding lead to those located at the center thereof.

Preferably, the wire is rectangular, and

in the bounding lead, the widths of the wires gradually decrease from the wires located at both ends of the bounding lead to those located at the center thereof, and the lengths of all the wires are the same.

Optionally, the chip on film is used for transmitting a data signal.

Alternatively, the chip on film is used for transmitting a gate driving signal.

Further, the display device comprises at least two chip on films for transmitting the gate driving signal, the chip on films each being connected to the fanout on the substrate through a bounding lead, and

in two adjacent bounding leads, an average area of the wires in the former bounding lead is smaller than that of the wires in the latter bounding lead.

Preferably, the number of wires in each of the two adjacent bounding leads is n, the area of the i^{th} wire in the former bounding lead being smaller than that of the i^{th} wire in the latter bounding lead, wherein 1≦i≦n.

The present disclosure has the following beneficial effects. In the technical solutions of the present disclosure, the areas of the wires located at both ends of the bounding lead are the largest, and the nearer a wire is to the center of the bounding lead, the smaller the area thereof. Because the larger the contacting area between the wire and the chip on film, the smaller the resistance of the wire, the resistances of the wires located at both ends of the bounding lead are the smallest, and the nearer a wire is to the center of the bounding lead, the larger the resistance thereof. However, in the fanout connected to the bounding lead, the wires located at both sides of the fanout have the largest resistances, and the nearer a wire is to the center of the fanout, the smaller the resistance thereof. In this case, for each wire in the bounding lead and a corresponding wire in the fanout, the sum of their resistances is set to be close to, or even the same as, the sum of the resistances of another wire in the bounding lead and of another corresponding wire in the fanout. As a result, the degrees of color cast throughout the pixels can be closer to each other. Therefore, under the condition that the space in the substrate is limited and the structure of the wires in the fanout is not altered, the embodiments according to the present disclosure can solve the technical problem of fanout mura of the pixels controlled by the wires located at both sides of the fanout, and thus improve the display effect of the display device.

Other features and advantages of the present disclosure will be further explained in the following description, and are partially become more readily evident therefrom, or be understood through implementing the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

In order to illustrate the technical solutions of the examples of the present disclosure more clearly, the accompanying drawings needed for describing the examples will be explained briefly. In the drawings:

FIG. 1 schematically shows a display device according to example 1 of the present disclosure,

FIG. 2 schematically shows a part of a bounding lead of FIG. 1,

FIG. 3 schematically shows a display device according to example 2 of the present disclosure, and

FIG. 4 schematically shows a part of a bounding lead of FIG. 3.

### DETAILED DESCRIPTION OF THE EMBODIMENTS

The present disclosure will be explained in detail with reference to the embodiments and the accompanying drawings, whereby it can be fully understood about how to solve the technical problem by the technical means according to the present disclosure and achieve the technical effects thereof, and thus the technical solution according to the present disclosure can be implemented. It is important to note that as long as there is no structural conflict, various embodiments as well as the respective technical features mentioned herein may be combined with one another in any manner, and the technical solutions obtained all fall within the scope of the present disclosure.

The present disclosure provides a display device comprising a substrate, and a chip on film (COF) connected to a fanout on the substrate through a bounding lead. The bounding lead comprises a plurality of parallel wires. In the bounding lead, the areas of the wires gradually decrease from the wires located at both ends of the bounding lead to those located at the center thereof.

In an example of the present disclosure, the areas of the wires located at both ends of the bounding lead are the largest, and the nearer a wire is to the center of the bounding lead, the smaller the area thereof. Because the larger the contacting area between the wire and the chip on film, the smaller the resistance of the wire, the resistances of the wires located at both ends of the bounding lead are the smallest, and the nearer a wire is to the center of the bounding lead, the larger the resistance thereof. However, in the fanout connected to the bounding lead, the wires located at both sides of the fanout have the largest resistances, and the nearer a wire is to the center of the fanout, the smaller the resistance thereof. In this case, for each wire in the bounding lead and a corresponding wire in the fanout, the sum of their resistances is set to be close to, or even the same as, the sum of the resistances of another wire in the bounding lead and of another corresponding wire in the fanout. As a result, the degrees of color cast throughout the pixels can be closer to each other. Therefore, under the condition that the space in the substrate is limited and the structure of the wires in the fanout is not altered, the examples according to the present disclosure can solve the technical problem of fanout mura of the pixels controlled by the wires located at both sides of the fanout, and thus improve the display effect of the display device.

### Example 1

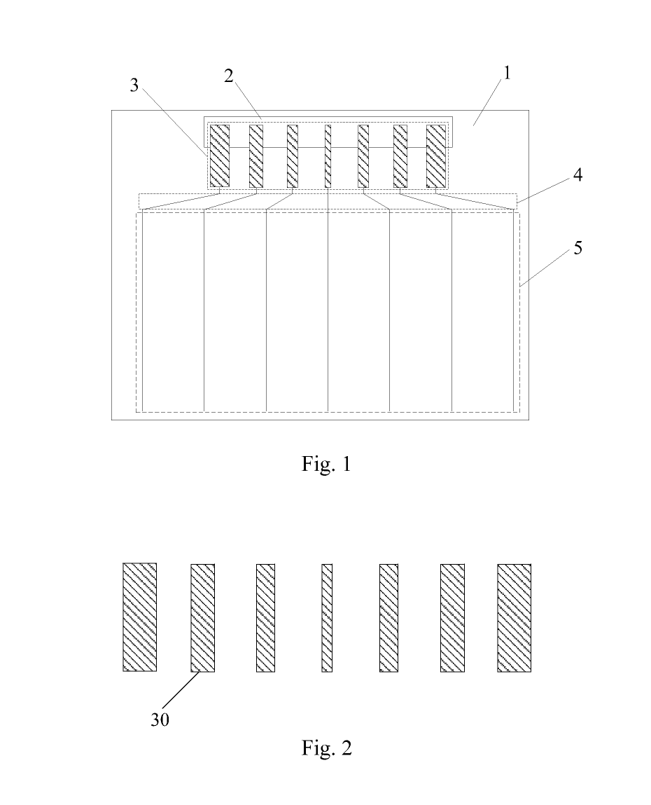

The chip on film according to the present example is used for transmitting a data signal. As shown in FIGS. 1 and 2, a chip on film 2 is connected to a fanout 4 on a substrate 1 through a bounding lead 3, and then connected to data lines in an active area 5. The bounding lead 3 comprises a plurality of parallel wires 30. In the bounding lead 3, the areas of the wires 30 gradually decrease from the wires 30 located at both ends of the bounding lead 3 to those located at the center thereof.

In an example of the present disclosure, the wire 30 is rectangular. And the widths of the wires gradually decrease from the wires 30 located at both ends of the bounding lead 3 to those located at the center thereof, and the lengths of all the wires 30 are the same.

In an example of the present disclosure, the resistances of the wires 30 located at both ends of the bounding lead 3 are the smallest, and the nearer a wire 30 is to the center of the bounding lead 3, the larger the resistance thereof. However, the wires located at both sides of the fanout 4 have the largest resistances, and the nearer a wire is to the center of the fanout 4, the smaller the resistance thereof. In this case, for each wire 30 in the bounding lead 3 and a corresponding wire in the fanout 4, the sum of their resistances is set to be close to, or even the same as, the sum of the resistances of another wire 30 in the bounding lead 3 and of another corresponding wire in the fanout 4. As a result, the degrees of color cast throughout the pixels can be closer to each other. Therefore, under the condition that the space in the substrate 1 is limited and the structure of the wires in the fanout 4 is not altered, the examples according to the present disclosure can solve the technical problem of fanout mura of the pixels controlled by the wires located at both sides of the fanout 4, and thus improve the display effect of the display device.

The wire 30 can also fixedly bond the chip on film 2 to the substrate 1. The bonding strength of wire 30 is dependent on the length thereof. Therefore, by arranging the same length for the wires 30, the bonding strengths of each of the wires 30 can be the same, so that the chip on film 2 can be bonded to the substrate 1 more uniformly and stably.

It should be noted that in other examples, the wire can also be made into other shapes, such as oval, trapezoid, and the like, as long as the condition that the wires located at both ends of the bounding lead have the smallest resistances, and the nearer a wire is to the center of the bounding lead, the larger the resistance thereof, is met.

### Example 2

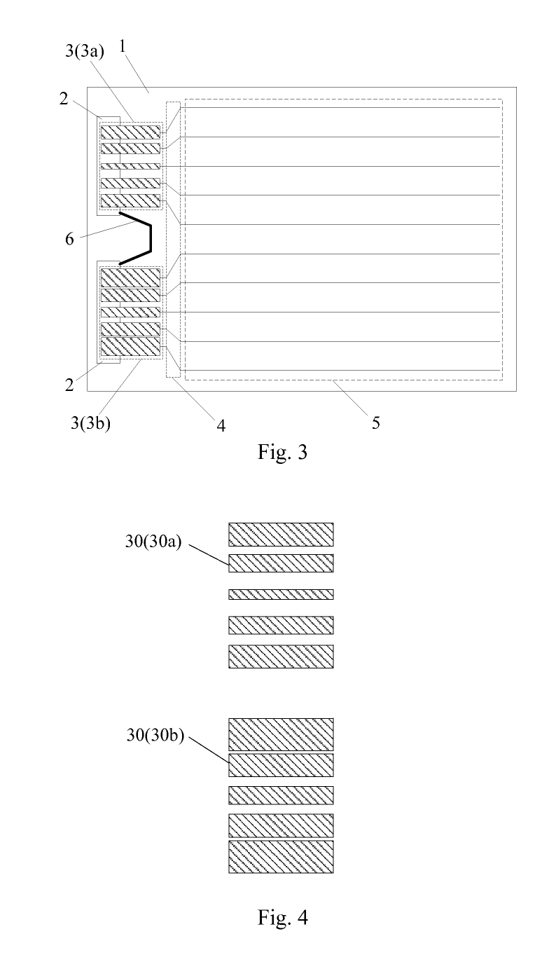

Example 2 is substantially the same as example 1, and the difference therefrom is that a chip on film for transmitting a gate driving signal is provided in example 2. As shown in FIGS. 3 and 4, the chip on film 2 is connected to the fanout 4 on the substrate 1 through the bounding lead 3, and then connected to gate lines in the active area 5. The bounding lead 3 comprises a plurality of parallel wires 30. In the bounding lead 3, the areas of the wires 30 gradually decrease from the wires 30 located at both ends of the bounding lead 3 to those located at the center thereof.

In an example of the present disclosure, the resistances of the wires 30 located at both ends of the bounding lead 3 are the smallest, and the nearer a wire 30 is to the center of the bounding lead 3, the larger the resistance thereof. However, the wires located at both sides of the fanout 4 have the largest resistances, and the nearer a wire is to the center of the fanout 4, the smaller the resistance thereof. In this case, for each wire 30 in the bounding lead 3 and a corresponding wire in the fanout 4, the sum of their resistances is set to be close to, or even the same as, the sum of the resistances of another wire 30 in the bounding lead 3 and of another corresponding wire in the fanout 4. As a result, the degrees of color cast throughout the pixels can be closer to each other. Therefore, under the condition that the space in the substrate 1 is limited and the structure of the wires in the fanout 4 is not altered, the examples according to the present disclosure can solve the technical problem of fanout mura of the pixels controlled by the wires located at both sides of the fanout 4, and thus improve the display effect of the display device.

Further, the display device usually comprises at least two chip on films for transmitting the gate driving signal. Two adjacent chip on films are connected with each other through a wire on array (hereinafter referred to as WOA). Since the WOA has a certain resistance, the waveform distortion of the gate driving signal outputted by the latter chip on film is more severe than that of the gate driving signal outputted by the former chip on film, especially at the connected position between the two adjacent chip on films. That is, the difference between the waveform of the gate driving signal on the last gate line of the former chip on film and that of the gate driving signal on the first gate line of the latter chip on film is particularly evident, causing a weak line, i.e., H-block, on the corresponding position of the liquid crystal display device. Consequently, the display effect is influenced.

In order to solve the above technical problem, the present disclosure provides the following technical solutions.

The present example will be explained with the two chip on films as shown in FIGS. 3 and 4. The two adjacent chip on films 2 are connected with each other through a wire on array 6. Each chip on film 2 is connected to the fanout 4 on the substrate 1 through a bounding lead 3. In two adjacent bounding leads, an average area of the wires 30a in a former bounding lead 3a is smaller than that of the wires 30b in a latter bounding lead 3b.

Specifically, the number of wires in each of the bounding leads is usually the same. In the present example, the number of wires 30 in each of the two adjacent bounding leads 3 is n, and the area of the i^{th} wire in the former bounding lead 3a is smaller than that of the i^{th} wire in the latter bounding lead 3b, wherein 1≦i≦n. That is, the area of any one of the wires 30a of the former bounding lead 3a is smaller than that of the wire 30b located at a corresponding position of the latter bounding lead 3b.

In the latter bounding lead 3b, the area of each wire 30b is larger than that of the wire 30a located at a corresponding position in the former bounding lead 3a, and thus the resistance of the wire 30b in the latter bounding lead is smaller, so that the sum of the resistance of the wire 30b in the latter bounding lead 3b and that of WOA 6 can be close to, or even the same with the resistance of the wire 30a in the former bounding lead 3a. As a result, the technical problem of H-block caused by the resistance of WOA 6 can be solved, and the display effect of the display device can be improved.

If the numbers of wires in the two adjacent bounding leads are different, the wires in the former bounding lead cannot accurately correspond to those in the latter bounding lead. However, as long as the average area of the wires in the former bounding lead is smaller than that of the wires in the latter bounding lead, the sum of the resistance of the wires in the latter bounding lead and that of the WOA can be close to, or even the same with the resistance of the wires of the former bounding lead.

It is important to note that the above example 1 and example 2 can be combined together. That is, in a display device, the technical solutions of the present disclosure can be applied to both a chip on film for transmitting data signal and a chip on film for transmitting gate driving signal.

The above embodiments are described only for better understanding, rather than restricting, the present disclosure. Any person skilled in the art can make amendments to the implementing forms or details without departing from the spirit and scope of the present disclosure. The scope of the present disclosure should still be subjected to the scope defined in the claims.

1. A display device, comprising a substrate and a chip on film connected to a fanout on the substrate through a bounding lead,
wherein the bounding lead comprises a plurality of parallel wires, and
in the bounding lead, the areas of the wires gradually decrease from the wires located at both ends of the bounding lead to those located at the center thereof.

2. The display device according to claim 1, wherein the wire is rectangular, and
in the bounding lead, the widths of the wires gradually decrease from the wires located at both ends of the bounding lead to those located at the center thereof, and the lengths of all the wires are the same.

3. The display device according to claim 1, wherein the chip on film is used for transmitting a data signal.

4. The display device according to claim 1, wherein the chip on film is used for transmitting a gate driving signal.

5. The display device according to claim 4, wherein the display device comprises at least two chip on films for transmitting the gate driving signal, the chip on films each being connected to the fanout on the substrate through a bounding lead, and
in two adjacent bounding leads, an average area of the wires in the former bounding lead is smaller than that of the wires in the latter bounding lead.

6. The display device according to claim 5, wherein the number of wires in each of the two adjacent bounding leads is n, and the area of the i^{th} wire in the former bounding lead is smaller than that of the i^{th} wire in the latter bounding lead, wherein 1≦i≦n.
